(19) United States
(12) Patent Application Publication
(10) Pub. No.: US 2004/0145387 A1
(43) Pub. Date: Jul. 29, 2004

(54) Integrated monitoring burn-in test method for multi-chip package

(76) Inventors: Geum-Jin Yun, Cheonan-city (KR); Jin-Sung Jung, Cheonan-city (KR); Seong-Goo Kang, Cheonan-city (KR); Jeong-Ho Bang, Yongin-city (KR); Byoung-Jun Min, Cheonan-city (KR)

Correspondence Address: HARNESS, DICKEY & PIERCE, P.L.C., P.O. BOX 8910, RESTON, VA, 20195, US

(21) Appl. No.: 10/759,267

(22) Filed: Jan. 20, 2004

(30) Foreign Application Priority Data
Jan. 20, 2003 (KR) 2003-3648

(51) Int. Cl. G01R 31/26

(52) U.S. Cl. 324/765

(57) ABSTRACT

A method for testing a multi-chip package formed of different types of semiconductor devices, using an integrated burn-in test program which can reduce throughput time, reduce the possibility of error by an operator, and reduce workload. A multi-chip package is tested in burn-in equipment capable of applying a plurality of scan control clock signals. An integrated burn-in test program requires fewer burn-in test programs to be uploaded, fewer contact tests, and fewer bin sorting operations.

### BACKGROUND OF THE INVENTION

This application claims the priority of Korean Patent Application No. 2003-3648 filed on Jan. 20, 2003 in the Korean Intellectual Property Office, the disclosure of which is incorporated herein in its entirety by reference.

1. Field of the Invention

The present invention relates to testing of a semiconductor package, and more particularly, to a monitoring burn-in test (MBT) for a multi-chip package.

2. Description of the Related Art

A conventional multi-chip package includes multiple semiconductor chips or semiconductor packages. Generally, the semiconductor chips or the semiconductor packages are of the same kind. However, recently, many different kinds of semiconductor chips or semiconductor packages have been integrated in the same multi-chip package for mobile phones, personal digital assists (PDA), and digital cameras. This multi-type, multi-chip package is called a fusion memory.

A fusion memory may include a DRAM, a SRAM, and a NAND flash memory. Whereas the SRAM is conventionally used as a buffer and working memory, DRAM or NAND flash memory is used as a data storing memory. Upon integrating the SRAM, the DRAM, and the flash memory into the multi-chip package, the size of the semiconductor package can be reduced by 40% in comparison with the size of each individual memory. Accordingly, a fusion memory can be used for compact electronic products, such as mobile phones, personal digital assistants, or digital cameras.

FIG. 1 is a graph showing a failure rate of a conventional semiconductor package. As shown in FIG. 1, generally, the failure rate of the semiconductor package has a higher value before 1,000 hours of use and after 25 years of service. A burn-in test is used to detect product failures within the first 1,000 service hours. In the burn-in test, the multi-chip package is tested under accelerated stresses such as temperature, voltage, and clock signal.

Depending on the semiconductor device to be tested, the burn-in test may be classified into a wafer level burn-in test and a package burn-in test. Depending on burn-in conditions, the burn-in test can also be classified into a static burn-in, a dynamic burn-in, and a monitoring burn-in.

The static burn-in test is carried out by applying a constant direct current, the dynamic burn-in test is carried out by applying a constant direct current in the form of a clock signal, and the monitoring burn-in test is conducted using equipment having a read/write and partial testing capability. FIG. 2 is a flow chart of a conventional monitoring burn-in test.

Referring to FIG. 2, a multi-chip package is loaded on a burn-in board. For example, the multi-chip package may contain a NAND flash memory device, a SRAM device, and a DRAM device. At S10, a burn-in test program for testing the NAND flash memory device is uploaded to the burn-in test equipment. After loading the burn-in board into a burn-in chamber, an electrical connection between the burn-in board and the chamber of the burn-in equipment is tested by a contact test at S11.

The above contact test is conducted manually by an operator looking at a monitor to detect whether there is a poor contact or not. If a poor contact is detected, the operator cuts off the power supply to the burn-in board and takes the proper action, such as repair.

At S12, the temperature of the burn-in chamber is raised to the burn-in test temperature of the NAND flash memory device. When the temperature reaches the burn-in test temperature of the NAND flash memory device, a burn-in test for the NAND flash memory device is conducted at S13. When the burn-in test of the NAND flash memory device is completed at S14, the temperature is lowered to about 50° C. at S15. The purpose of lowering the temperature to 50° C. is to remove defective multi-chip packages. If the door of the burn-in chamber at high temperature is opened, the operator could get injured. Therefore, the door is designed to open at a temperature below 50° C. to protect the operator.

When the temperature is lowered, multi-chip packages having defects are sorted out and removed at S16. Afterward, a burn-in test program for the SRAM device which is included in the multi-chip package is uploaded to the burn-in equipment by the operator. Before commencing the test, another contact test is conducted at S11a. Upon completion of the contact test, the temperature of the chamber is raised to the burn-in test temperature of the SRAM device at S12a and the burn-in test for the SRAM is conducted at S18. After the test is completed at S19, the temperature of the chamber is lowered to below 50° C. at S15, then, the multi-chip packages having defective devices are sorted out and removed at S20.

Finally, a burn-in test program for testing the DRAM device is uploaded to the burn-in equipment at S21. After uploading the burn-in test program for testing the DRAM device, another contact test is conducted at S11b, and then the temperature of the chamber is raised at S12b to the burn-in test temperature of the DRAM. When the temperature of the chamber reached the test temperature, the burn-in test of the DRAM is conducted at S22. After the test is completed at S23, the temperature of the chamber is lowered to below 50° C. and the multi-chip packages are sorted at S24 based on the burn-in test results, and the multi-chip packages having defected devices are removed.

As presented above, the burn-in test for each device included in a multi-chip package is executed for each chip using a different burn-in test program in the burn-in test equipment. This is because there are only two scan control clock signals for the monitoring burn-in test in the burn-in test equipment.

Generally, a burn-in test equipment groups semiconductor packages which share internal signal lines on a burn-in board using the scan control clock signals. For example, assuming a monitoring burn-in test is conducted with a burn-in board loaded with one hundred multi-chip packages, the number of I/O pins required for this test may be in the thousands, however, the I/O pins equipped in the burn-in test equipment are less than one hundred. Therefore, the burn-in equipment groups the semiconductor packages loaded onto the burn-in board and applies the scan control clock signals.

Accordingly, in the conventional art, a simultaneous monitoring burn-in test for a multi-chip package is impossible. Therefore, the monitoring burn-in test is conducted by inserting an additional burn-in board for each multi-chip package. In this case, the number of required burn-in boards increases, the monitoring burn-in test needs to be performed more than twice per each multi-chip package, which reduces the productivity of the test. In addition, the conventional burn-in test for a multi-chip package has the following drawbacks. First, there is a high possibility of an error during uploading the burn-in test program to the burn-in equipment, because an operator has to load three programs for testing a multi-chip package, one for each type of memory.

Second, after a burn-in test for each semiconductor device in a multi-chip package, the temperature of the chamber needs to be lowered to remove the defective packages. This increases the workload and is time consuming.

Third, the contact test is carried out after each loading of a new burn-in board, thereby further increasing the workload.

### SUMMARY OF THE INVENTION

Exemplary embodiments of the present invention are directed to a method of testing a multi-chip package using an integrated burn-in test program, and more particularly, a burn-in test for a multi-chip package using an integrated burn-in test program in burn-in equipment which is capable of applying a plurality of scan control clock signals.

Exemplary embodiments of the present invention are directed to a method of testing a multi-chip package, formed of semiconductor chips of multiple kinds, including loading a multi-chip package into a chamber of burn-in equipment which is capable of applying a plurality of scan control clock signals, uploading an integrated burn-in test program for testing the multi-chip package to the burn-in equipment, and conducting a burn-in test of the multi-chip package using the integrated burn-in test program.

In an exemplary embodiment of the present invention, the semiconductor device performs a memory function in a semiconductor package or semiconductor chip. In an exemplary embodiment, each semiconductor device has a different burn-in temperature and is tested using a different test method. In another exemplary embodiment, the multi-chip package is in the form of a TBGA (thin ball grid array).

In an exemplary embodiment, the integrated burn-in test program is designed to set different testing conditions for different semiconductor devices, using a multiplexer selection function. In an exemplary embodiment, the integrated burn-in test program includes a masking function of an I/O terminal or the ability to set a burn-in temperature for each semiconductor device.

In an exemplary embodiment, after loading the multi chip package to the burn-in equipment, a contact test may be performed to detect whether the burn-in board loaded with the multi-chip package has a good electrical connection with the multi-chip package.

In an exemplary embodiment of the present invention, the burn-in test is a monitoring burn-in test and the integrated burn-in test program requires only one bin sorting after the burn-in test.

Exemplary embodiments of the present invention are directed to an integrated burn-in test method for testing a multi-chip package, including providing the multi-chip package formed of multiple types of semiconductor device and testing the multi-chip package with an integrated burn-in test program.

Exemplary embodiments of the present invention are directed to an integrated burn-in test method for testing a multi-chip package, including providing the multi-chip package formed of multiple types of semiconductor device and testing the multi-chip package with an integrated burn-in test program. The testing further includes performing a contact test once for all different types of semiconductor devices of the multi-chip package, blocking some I/O terminals during testing of some semiconductor devices, wherein the blocking is defined by an I/O masking function, setting a specific burn-in temperature condition for different types of semiconductor devices, conducting a burn-in test for the multiple types of semiconductor devices by applying a specific test condition for each semiconductor device, wherein the specific test condition is defined by a multiplexer selection function. The method further includes bin sorting once for all different types of semiconductor devices of the multi-chip package based on the testing result.

Exemplary embodiments of the present invention may reduce process time, reduce the possibility of operator error, reduce workload, and/or increase test productivity.

### BRIEF DESCRIPTION OF THE DRAWINGS

FIG. 1 is a graph showing a failure rate of a conventional semiconductor product.

FIG. 2 is a flow chart of a conventional monitoring burn-in test for a multi-chip package.

FIG. 3 is a cross-sectional view of a conventional multi-chip package.

FIG. 4 is a block diagram of a burn-in equipment used for a monitoring burn-in test process for a multi-chip package, according to an exemplary embodiment of the present invention.

FIG. 5 is a flow chart of a monitoring burn-in test for a multi chip package, according to an exemplary embodiment of the present invention.

FIG. 6 is a graph showing the process time of a conventional monitoring burn-in test.

FIG. 7 is a graph showing the process time of the monitoring burn-in test according to an exemplary embodiment of the present invention.

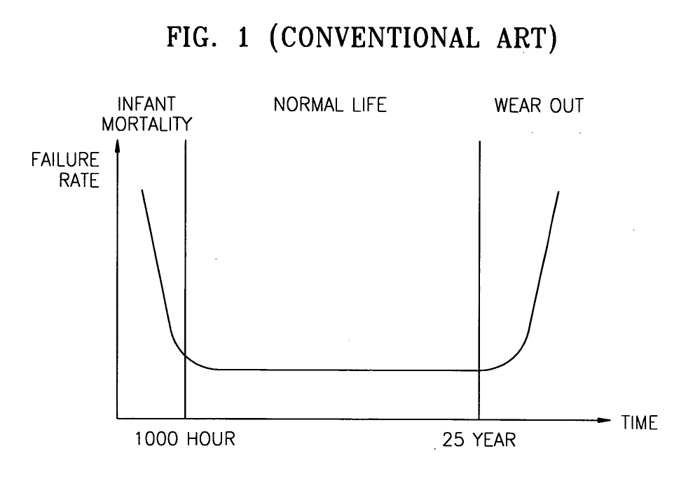

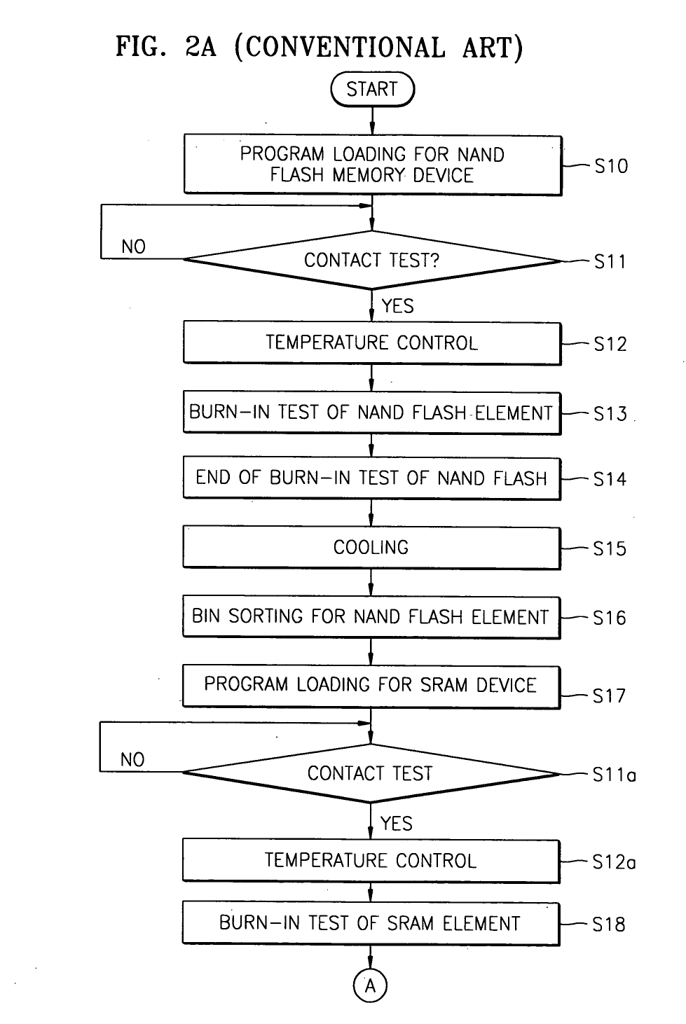

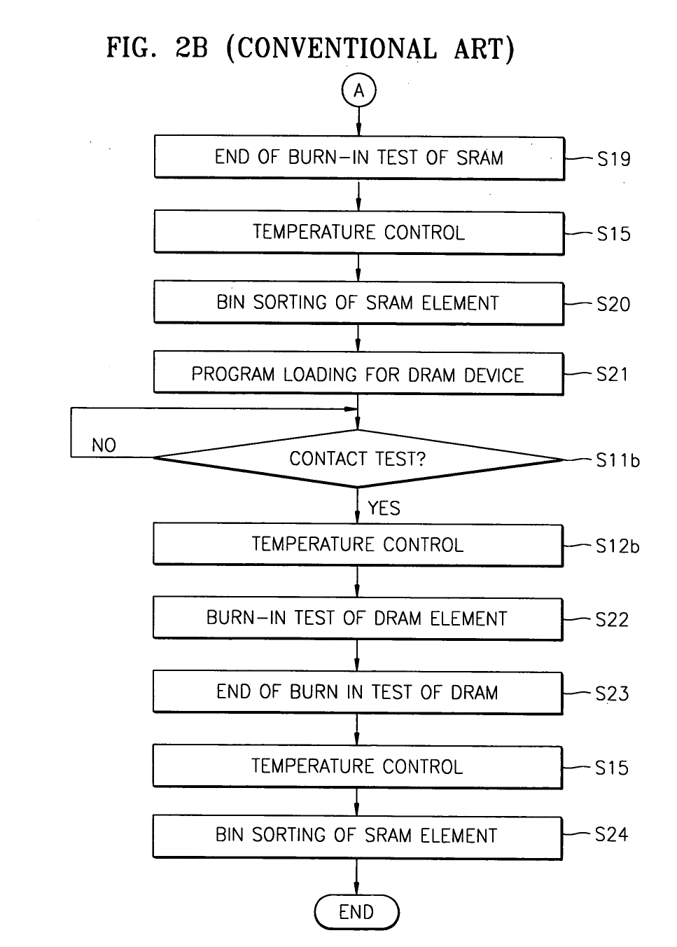

### DETAILED DESCRIPTION OF EXEMPLARY EMBODIMENTS OF THE INVENTION

Hereinafter, exemplary embodiments of the present invention will be described more fully with reference to the accompanying drawings. However, this invention may be embodied in many different forms and should not be construed as being limited to the exemplary embodiments set forth herein. Rather, theses exemplary embodiments are provided so that this disclosure is thorough and complete and fully conveys the concept of the invention to those skilled in the art.

The phrase multi-chip package in the context of this invention shall be interpreted in a broad sense and not be confined to a specific multi-chip package as depicted in the exemplary embodiments of the present invention.

Exemplary embodiments of the present invention can be embodied in many different ways without departing from the spirit and scope of the invention as defined by the appended claims. For example, in an exemplary embodiment, the multi-chip package is defined as an integrated form of a NAND flash memory device, an SRAM device, and a DRAM device, but could be an integrated form of a NAND flash memory device and a SRAM device or an integrated form of different semiconductor devices having different functions. Therefore, the present invention should not be construed as being limited to the exemplary embodiments set forth herein.

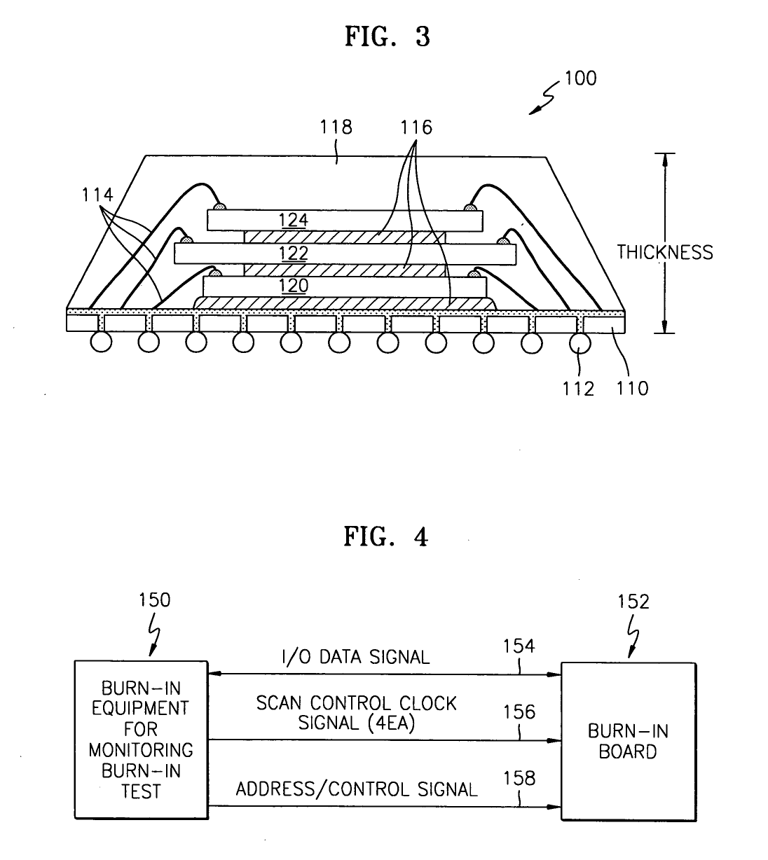

FIG. 3 is a cross-sectional view of a conventional multi-chip package.

Referring to FIG. 3, semiconductor chips 120, 122, and 124 repesenting a NAND flash memory device, a SRAM device, and a DRAM device are integrated into a multi-chip package 100. By using an adhesive material 116, such as an adhesive or an adhesive tape, gaps between the semiconductor chips 120, 122, and 124, and between the semiconductor chip 120 and a substrate 110 are formed. Also, each semiconductor chip 120, 122, and 124 is interconnected to the substrate 110 by an individual wire 114, such as a bonding wire. The semiconductor chips 120, 122, and 124 may be connected to external devices through solder balls 112 which act as external connection terminals of the substrate 110. The integrated multi-chip package 100 may be sealed by a sealing resin 118 to protect it from external impact.

Although, the multi-chip package in FIG. 3 is formed of three semiconductor chips, the present invention may be applied to a multi-chip package formed of any number of semiconductor chips, any type of semiconductor chips, and may extend to a multi-chip package formed of semiconductor packages instead of semiconductor chips. Also, a multi-chip package formed of semiconductor chips acting as a memory device has been described as an example, but the present invention further can extend to a multi-chip package formed of semiconductor chips acting as different devices, other than memory devices.

FIG. 4 is a block diagram of a burn-in equipment used for a monitoring burn-in test for a multi chip-package, according to an exemplary embodiment of the present invention.

Referring to FIG. 4, generally, there are three signal wires between a burn-in equipment 150 and a burn-in board 152. The first wire is for an I/O data signal 154 of a semiconductor package, the second wire is for the scan control clock signal 156 by which the semiconductor packages loaded on the burn-in board are grouped, and the third wire is for an address/control signal 158 which designates an address of the semiconductor devices loaded on the burn-in board 152 and applies a control signal. In exemplary embodiments of the present invention, multiple scan control clock signals 156, e.g., four signals, are employed. Accordingly, the integrated monitoring burn-in test can be performed even when more than two multi-chip packages are loaded on the burn-in board 152.

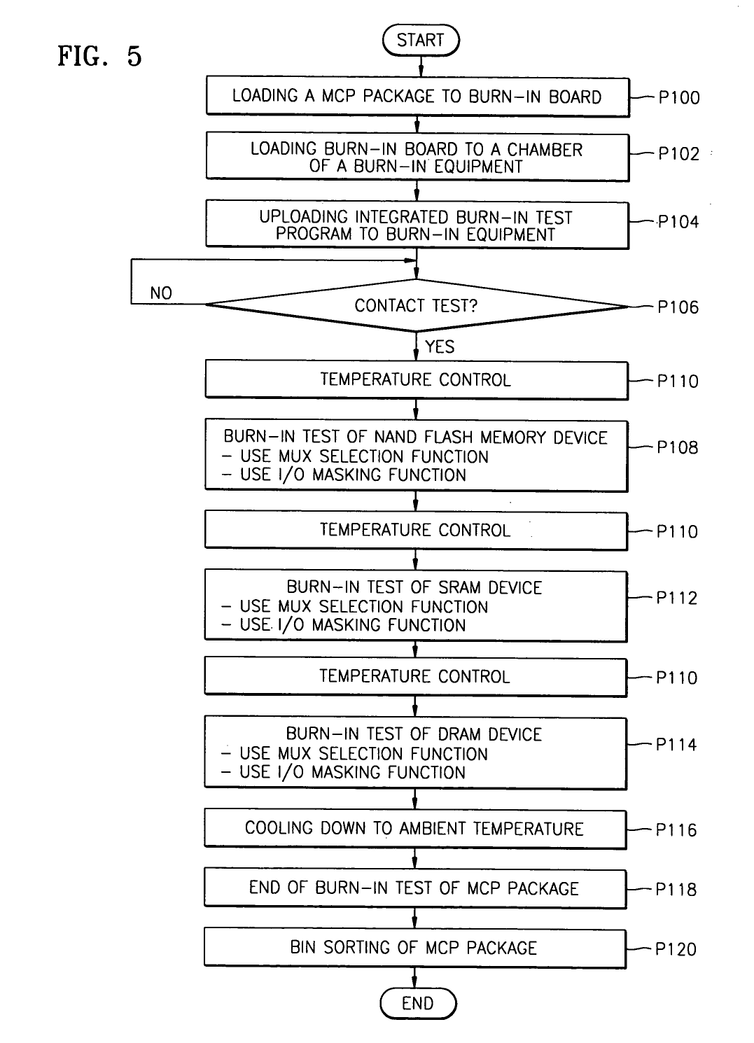

FIG. 5 is a flow chart of a monitoring burn-in test method for a multi-chip package, according to an exemplary embodiment of the present invention.

As described above, in the conventional art, the monitoring burn-in test was conducted for each individual semiconductor device contained in a multi-chip package. In contrast, in exemplary embodiments of the present invention, all semiconductor devices in a multi-chip package are tested in one process using an integrated monitoring burn-in test program.

Referring to FIG. 5, a multi-chip package, which is an integrated package including a NAND flash memory device, a SRAM device, and a DRAM device, is loaded on a burn-in board at P100 by a conventional method. The burn-in board may be a printed circuit board (PCB) for conducting a monitoring burn-in test of a unit multi-chip package. A plurality of sockets for connecting to the multi-chip package are mounted on the burn-in board.

A multiple numbers of burn-in boards loaded with the multi-chip package are loaded into the chamber of a burn-in equipment at P102. The burn-in chamber may be formed to electrically connect the multiple numbers of burn-in boards, and is where accelerated stresses, such as temperature, voltage, and read/write signals, may be applied to the multi-chip package. An integrated burn-in test program is uploaded at P104 to the burn-in equipment by an operator. Upon loading the program, the operator performs a contact test at P106 to examine the electrical connection between the burn-in board and the burn-in chamber and determine whether the connection is correct or not.

At P110, the integrated burn-in test program adjusts the chamber temperature to the test level of the NAND flash memory device burn-in temperature by controlling the hardware of the burn-in equipment. When the temperature reaches the test level of the NAND flash memory device burn-in temperature, a burn-in test for the NAND flash memory device is conducted at P108. In an exemplary embodiment, the integrated burn-in test program performs the burn-in test for the NAND flash memory device using a multiplexer selection function and an I/O masking function, described in more detail below.

The monitoring burn-in test for a NAND flash memory device, a SRAM device, and a DRAM device are different. For example, for the monitoring burn-in test for the NAND flash memory device, the test is performed using the multiplexer function for the AX address, AY address, and the data terminals, while for the SRAM device, the monitoring burn-in test is conducted without the multiplexer function. For the DRAM device, the monitoring burn-in test is conducted using the multiplexer function for the AX address and AY address. In order to perform the monitoring burn-in test accommodating such different testing conditions, in an exemplary embodiment, the integrated burn-in test program is designed to include all three testing conditions. The monitoring burn-in test for a specific semiconductor device, such as the NAND flash memory device, is designed to call one test condition among those three programs as a subroutine program. This function is called the multiplexer selection function.

On the other hand, the I/O masking function is a blocking function of I/O terminals not in use. Semiconductor devices integrated into a multi-chip package do not have the same number of I/O terminals. For example, the NAND flash memory device may have 8 output pins, the SRAM device may have 16 output pins, and the DRAM device may have 16 output pins. However, the number of sockets of the burn-in board is conventionally designed to use 16 output terminals.

In this case, the monitoring burn-in test for the NAND flash memory device uses only eight output terminals out of the sixteen assigned output terminals and the remaining eight terminals need not be used. This is because if there is any unwanted output from the eight unused output terminals, the monitoring burn-in test becomes impossible. Therefore, when testing semiconductor devices using the integrated monitoring burn-in test program, the I/O pin terminals of the burn-in equipment unconnected with the pins of every semiconductor device are blocked. This function is referred to as an I/O masking function.

On completion of the monitoring burn-in test for NAND flash memory device using the multiplexer function and I/O masking function, the integrated burn-in test program raises the chamber temperature of the burn-in equipment to the test temperature level of a different semiconductor device such as the SRAM device at P110.

In the conventional art, it is necessary to upload an individual burn-in test program for each semiconductor device to be tested, and the chamber temperature should be lowered below 50° C. in order to remove the defective chips for every semiconductor device. However, the use of an integrated monitoring burn-in test program of exemplary embodiments of the present invention enables a direct shift from a test temperature level to another test temperature level, thereby decreasing the burn-in test time.

Also, in the conventional art, the uploading operation of each burn-in test program to the burn-in equipment must be performed three times (or as many times as there are different chips in the package). Accordingly, there is a high possibility of an error during the uploading operation to the burn-in equipment by the operator. In exemplary embodiments of the present invention, however, only one uploading of the program (usually at the beginning of the burn-in test) is necessary, thereby reducing the possibility of error by the operator. Further, in the conventional art, contact tests must be conducted three times (or as many times as there are different chips in the package), thereby increasing workload. However, in exemplary embodiments of the present invention, only one contact test (identified in FIG. 5 as P106) is required before the integrated burn-in test program commences, thereby reducing the workload ⅔ when compared to that of the conventional art.

When the chamber temperature reaches the burn-in test temperature level of the SRAM device, the monitoring burn-in test of the SRAM device is conducted at P112 using the multiplexer selection function and I/O masking function. Once the monitoring burn-in test of the SRAM device is completed, the integrated burn-in test program controls the chamber temperature at P110 to adjust the temperature level to a burn-in test condition of another semiconductor device, such as the DRAM device.

Afterward, when the chamber temperature reaches the burn-in test temperature level of the DRAM device, the monitoring burn-in test of the DRAM device is conducted at P114 using the multiplexer selection function and the I/O masking function. Once the monitoring burn-in test of the DRAM device is completed, the overall integrated monitoring burn-in test of the multi-chip package test is finished at P118. The chamber temperature is lowered below 50° C., that is, below the temperature setting value for opening the chamber door. At P120, bin sorting for the multi-chip package is conducted based on the integrated monitoring burn-in test result.

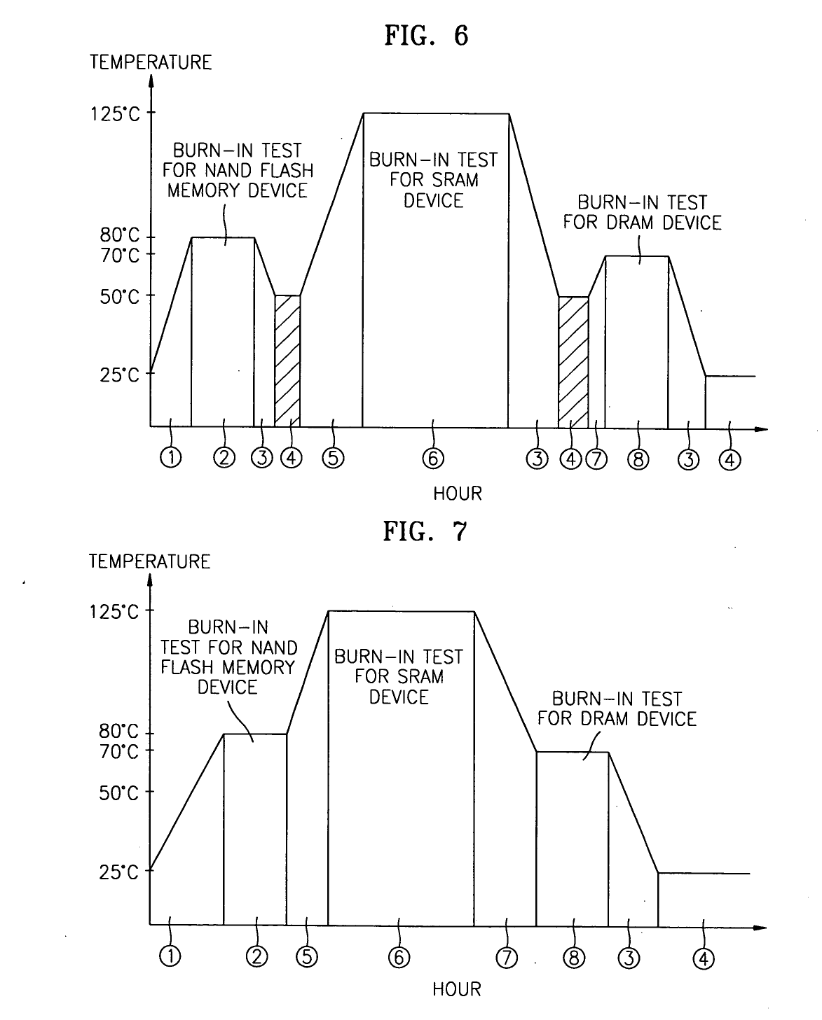

FIG. 6 is a graph showing the process time of a conventional monitoring burn-in test. Referring to FIG. 6, the graph shows the variation of the chamber temperature vs. time for a multi-chip package as shown in FIG. 4 when the burn-in temperature of the NAND flash memory device is 80° C., the SRAM device is 125° C., and the DRAM is 70° C. Section \mathring{1} indicates the time required to increase the chamber temperature to 80° C., which is the temperature level for conducting the burn-in test of the NAND flash memory device, section \mathring{2} indicates the time required for conducting the burn-in test of NAND flash memory device, section \mathring{3} indicates the time required for lowering the chamber temperature below 50° C. to open the chamber door, section \mathring{4} indicates the time required for sorting the multi-chip package based on the test result, section \mathring{5} indicates the time required for increasing the chamber temperature to 125° C. which is the temperature for conducting the burn-in test of the SRAM device, section \mathring{6} indicates the time required for conducting the burn-in test of the SRAM device, section \mathring{7} indicates the time required for increasing the chamber temperature to 70° C., which is the temperature for the burn-in test of the DRAM device after cooling the chamber temperature below 50° C. for opening, and section \mathring{8} indicates the time required for conducting the burn-in test of DRAM device.

As shown, the process is time consuming, mainly because the operations of lowering the chamber temperature in sections \mathring{3} and \mathring{4} to conduct bin sorting three times, upload a different burn-in test program to the burn-in equipment, and conduct another contact test.

FIG. 7 is a graph showing the process time of the monitoring burn-in test according to an exemplary embodiment of the present invention.

Referring to FIG. 7, the overall burn-in test time is reduced in comparison to the conventional technique due to the absence of the section \mathring{3}, for cooling the chamber below 50° C., and section \mathring{4}, for uploading a different burn-in test program.

Consequently, the integrated burn-in test method of exemplary embodiments of the present invention reduces burn-in test time reduce the possibility of an error by an operator, and increase productivity by reducing workload.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An integrated burn-in test method for testing a multi-chip package, comprising:
loading the multi-chip package formed of multiple kinds of semiconductor devices, to a chamber of a burn-in equipment capable of applying a plurality of scan control clock signals;
uploading an integrated burn-in test program to the burn-in equipment for testing the multi-chip package; and
conducting a test of the multi-chip package using the integrated burn-in test program.

2. The method of claim 1, wherein the semiconductor device is a semiconductor package.

3. The method of claim 1, wherein the semiconductor device is a semiconductor chip.

4. The method of claim 1, wherein the multi-chip package performs a memory function.

5. The method of claim 1, wherein the test is conducted for each semiconductor device of the multi-chip package at a different temperature.

6. The method of claim 1, wherein the multi-chip package is loaded on a burn-in board and the burn-in board is loaded in the chamber of burn-in equipment.

7. The method of claim 1, wherein the multi-chip package is in the form of a TBGA (thin ball grid array).

8. The method of claim 1, wherein the integrated burn-in test program uses a multiplexer selection function for applying a desired test condition during testing of each semiconductor device.

9. The method of claim 1, wherein the integrated burn-in test program has an I/O masking function for blocking some I/O terminals.

10. The method of claim 1, wherein the integrated burn-in test program has a function of setting a burn-in temperature condition for different kinds of semiconductor devices.

11. The method of claim 6, wherein after loading the multi-chip package on the burn-in board to the chamber of the burn-in equipment, a contact test is conducted to examine whether an electrical connection of the burn-in board is correct.

12. The method claimed in claim 1, wherein the burn-in test is a monitoring burn-in test.

13. The method of claim 1, wherein the integrated burn-in test program requires only one time bin sorting based on the burn-in test result.

14. An integrated burn-in test method for testing a multi-chip package, comprising:
loading the multi chip-package including different kinds of semiconductor devices on a burn-in board;
loading the burn-in board into a chamber of a burn-in equipment capable of applying a plurality of scan control clock signals;
uploading an integrated burn-in test program to test different kinds of semiconductor devices to the burn-in equipment;
conducting a contact test for the burn-in board to examine an electrical connection;
conducting a burn-in test for the different kinds of semiconductor devices using a multiplex selection function of the integrated burn-in test program loaded to the burn-in equipment;
ending the burn-in test for different kinds of semiconductor devices; and
bin sorting the multi-chip package based on the burn-in test result.

15. The method of claim 14, wherein when burn-in test for different kinds of semiconductor devices are performed sequentially and the integrated burn-in test program controls the chamber temperature according to a test temperature for an individual semiconductor device.

16. The method of claim 14, wherein each semiconductor device performs a memory function.

17. The method of claim 14, wherein the integrated burn-in test program has an I/O masking function blocking function some I/O terminals.

18. The method of claim 17, wherein each semiconductor device of the multi-chip package has a different number of I/O terminal pins.

19. The method of claim 14, wherein the multi-chip package is in the form of a TBGA (thin ball grid array).

20. The method of claim 14, wherein the burn-in test is a monitoring burn-in test.

21. An integrated burn-in test method for testing a multi-chip package, comprising:
providing the multi-chip package formed of multiple types of semiconductor device; and
testing the multi-chip package with an integrated burn-in test program.

22. The method of claim 21, wherein the testing includes applying a specific test condition during testing of each semiconductor device, wherein the specific test condition is defined by a multiplexer selection function.

23. The method of claim 21, wherein the testing includes blocking some I/O terminals during testing of some semiconductor devices, wherein the blocking is defined by an I/O masking function.

24. The method of claim 21, wherein the testing includes setting a specific burn-in temperature condition for different types of semiconductor devices.

25. The method of claim 21, wherein the testing includes performing a contact test once for all different types of semiconductor devices of the multi-chip package.

26. The method of claim 21, further comprising:
bin sorting once for all different types of semiconductor devices of the multi-chip package based on the testing result.

27. An integrated burn-in test method for testing a multi-chip package, comprising:
providing the multi-chip package formed of multiple types of semiconductor device;
testing the multi-chip package with an integrated burn-in test program, including
performing a contact test once for all different types of semiconductor devices of the multi-chip package,
blocking some I/O terminals during testing of some semiconductor devices, wherein the blocking is defined by an I/O masking function,
setting a specific burn-in temperature condition for different types of semiconductor devices,
conducting a burn-in test for the multiple types of semiconductor devices by applying a specific test condition for each semiconductor device, wherein the specific test condition is defined by a multiplexer selection function; and
bin sorting once for all different types of semiconductor devices of the multi-chip package based on the testing result.
